(19) United States
(12) Patent Application Publication
(10) Pub. No.: US 2011/0238346 A1
(43) Pub. Date: Sep. 29, 2011

(54) ELECTROSTATIC DISCHARGE AUTOMATIC DETECTION SYSTEM

(75) Inventors: Jen-Fu SONG, TAIPEI (TW); Chun-Hao CHU, TAIPEI CITY (TW); Shu-Kuei TSUI, TAIPEI CITY (TW); Wen-Lung HUANG, TAIPEI CITY (TW)

(73) Assignee: INVENTEC CORPORATION, TAIPEI CITY (TW)

(21) Appl. No.: 12/791,875

(22) Filed: Jun. 2, 2010

(30) Foreign Application Priority Data
Mar. 29, 2010 (TW) 99109430

(51) Int. Cl. G01R 19/00; G06F 19/00

(52) U.S. Cl. 702/65

(57) ABSTRACT

The present invention provides an automatic electrostatic discharge (ESD) detection system connected to a plurality of current loops. For each of the current loops, the automatic ESD detection system can detect a plurality of electrical devices connected in sequence on the one current loop, and check if the electrical devices have abnormal ESD. The automatic ESD detection system includes a micro-controller, a plurality of circuit connection ports, a metrology unit, a circuit switching unit, a prompt unit, and two ground wires, wherein when one of the circuit connection ports is switched to be connected to the metrology unit, the one of the circuit connection ports remains electrically connected to one of the ground wires.

### RELATED APPLICATIONS

This application claims priority to Taiwan Application Serial Number 99109430, filed Mar. 29, 2010, which is herein incorporated by reference.

### BACKGROUND

1. Field of Invention

The present invention relates to an automatic electrostatic discharge (ESD) detection system and particularly to the automatic ESD detection system applied on the current loops in production lines.

2. Description of Related Art

In a conventional work environment, a production line generally includes several workstations, processing tools, etc., which are connected to a current loop in sequence. To prevent static electricity carried by or accumulated on operators from damaging electrical devices, electrical components, and measuring tools in a current route; or from damaging electrical products in a production line, these processing tools are usually electrically connected to ground via a common ground point, and the operators also wear wrist straps that are connected to the common ground point via conducting wires to release static electricity carried by or accumulated on the operators.

With regard to measuring electrostatic discharge (ESD) in production lines, ISO standards have provided specific resistance values for main production lines and branched production lines respectively. The wirings among the workstations and processing tools in a production line is quite complex, and the current method for measuring the resistance values in the production line is to use a multimeter to respectively perform periodical measurements on each set of circuits. However, it sometimes takes a lot of time to find the circuits for measurement due to complex wirings and failing to mark the branched circuits at the time of circuit planning. On the other hand, when circuit interruption or aging occurs, if such phenomenon cannot be found immediately, an unsafe factor of failing to direct static electricity to ground will be caused while the circuit is being measured.

Therefore, it is desirable to have a more efficient and safer ESD detection device.

### SUMMARY

In view of the above description, the present invention mainly provides an automatic electrostatic discharge (ESD) detection system which can be connected to a plurality of current loops. For each of the current loops, the ESD detection system can detect a plurality of electrical devices connected in sequence in a single current loop, and check if the electrical devices have abnormal ESD. The automatic ESD detection system of the present invention includes a micro-controller, a plurality of circuit connection ports, a metrology unit, a circuit switching unit, and a prompt unit. The micro-controller is used to obtain measurement data and process the measurement data, thereby generating a detection result and sending out the detection result externally. The plurality of circuit connection ports are respectively connected to the current loops. The metrology unit is used to measure the resistance value of one of the current loops, and transmit the resistance value back to the micro-controller. The circuit switching unit is controlled by the micro-controller to periodically switch one of the circuit connection ports to being connected with the metrology unit. The prompt unit is controlled by the micro-controller for sending a prompt signal based on the detection result.

The foregoing micro-controller compares the resistance value measured by the metrology unit with a predetermined value. If the resistance value is greater than the predetermined value, it is determined that the current loop with the resistance value has abnormal ESD.

According to one embodiment, the automatic ESD detection system of the present invention further includes two ground wires which are respectively and simultaneously connected to the circuit connection ports, wherein when being switched to being connected to the metrology unit, one of the circuit connection ports remains electrically connected to one of the ground wires.

According to one embodiment, the automatic ESD detection system of the present invention further includes a communication unit connected to the micro-controller. The communication unit is controlled by the micro-controller for transmitting the detection result to a remote monitor program. The remote monitor program is used to show the current loop with abnormal ESD based on the detection result.

Therefore, when the automatic ESD detection system of the present invention is used to respectively detect the plurality of electrical devices connected in sequence on each of the current loops and check if the electrical devices have abnormal ESD, the automatic ESD detection system not only can provide a feature of automatically uploading the measuring data and information, but also can provide an alarm with a warning light and a buzzer or can inform the remote managers by an automatically uploading feature via a network when the automatic ESD detection system of the present invention detects that at least one of the current loops has abnormal ESD. The present invention can save human resources and time for measuring the ESD of main production lines and branched production lines, and also can improve the problem that there are too many circuits to distinguish the circuits of the main/branched production lines from a messy situation induced by having too many circuits. By using the automatic ESD detection system of the present invention, many sets of current loops and sub-loops can be expanded in a tree-like branch structure and connected in sequence.

Moreover, by using a method for designing current loops to respectively and simultaneously connect the two ground wires with the circuit connection ports, the automatic ESD detection system of the present invention ensures that when interruption of one ground wire occurs, the current loops being measured or not being measured can remain grounded, and further provides a function for safely protecting the circuit from ESD damage.

### BRIEF DESCRIPTION OF THE DRAWINGS

FIG. 1 is a schematic diagram of an ESD detection system according to one embodiment of the present invention.

FIGS. 2a and 2b are schematic diagrams of an ESD detection system of the present invention applied to current loops.

### DESCRIPTION OF THE PREFERRED EMBODIMENTS

According to one embodiment, an automatic ESD detection system is provided. The automatic ESD detection system can be connected to a plurality of current loops. For each of the current loops, the ESD detection system can detect a plurality of electrical devices connected in sequence in the single current loop, and check if the electrical devices have abnormal ESD. Hereafter, the descriptions of the preferred embodiments of the present invention are provided with drawings, and the detail descriptions of the present invention are also provided.

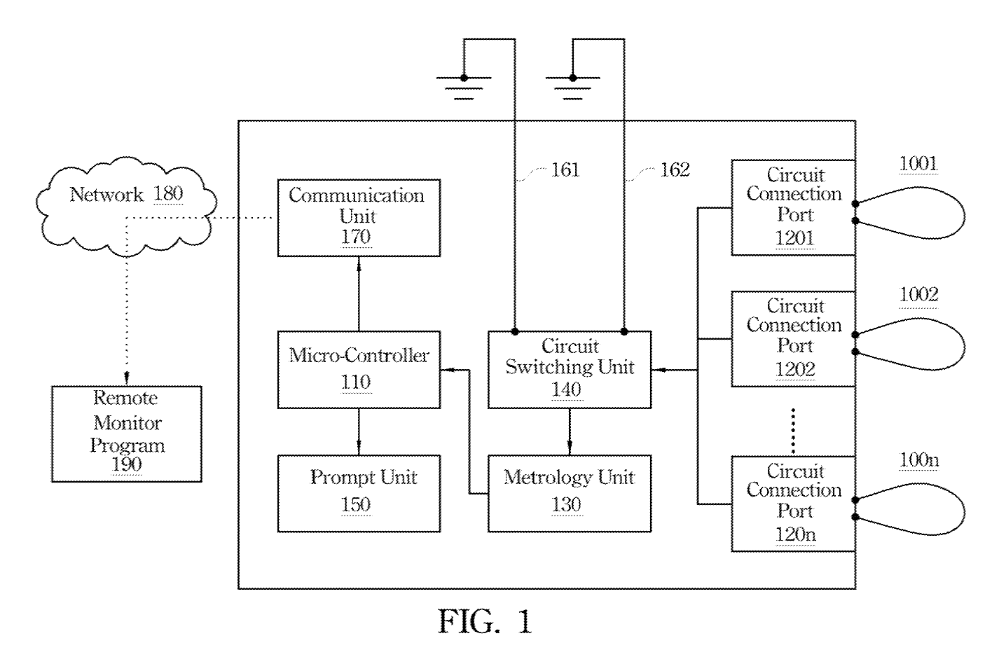

Refer to FIG. 1. FIG. 1 is a schematic diagram of an ESD detection system according to one embodiment of the present invention. The automatic ESD detection system 100 of the present invention includes a micro-controller 110, a plurality of circuit connection ports 1201 to 120n, a metrology unit 130, a circuit switching unit 140, a prompt unit 150, and two ground wires 161 and 162.

The plurality of circuit connection ports 1201 to 120n are respectively connected to a plurality of current loops 1001 to 100n, wherein each of the current loops includes a plurality of electrical devices connected in sequence therein (not shown).

The metrology unit 130 is used to measure a resistance value of one of the current loops 1001 to 100n, and transmit the resistance value back to the micro-controller 110.

For respectively measuring the resistance value of one of the current loops 1001 to 100n by the metrology unit 130, the circuit switching unit 140 is controlled by the micro-controller 110 by switching relay circuits to periodically switch one of the circuit connection ports 1201 to 120n to being connected with the metrology unit 130.

The micro-controller 110 obtains the resistance value measured by the metrology unit 130, and processes information of the resistance value to generate a detection result, i.e. that the micro-controller 110 will compare the measured resistance value with a predetermined value, such as, but not limited to, 2 ohm, and if the resistance value is greater than the predetermined value, it is determined that the one of the current loops 1001 to 100n with the resistance value has abnormal ESD and the detection result can be sent out externally.

The prompt unit 150 can be a warning light or a buzzer controlled by the micro-controller 110. Based on the detection result produced by the micro-controller 110, the prompt unit 150 can send a prompt signal, such as warning lights or warning sounds.

The ground wires 161 and 162 are respectively and simultaneously connected to the circuit connection ports 1201 to 120n such that all the current loops 1001 to 100n are individually connected to circuit connection ports 1201 to 120n and can be grounded via the ground wire 161 or the ground wire 162. When one of the circuit connection ports 1201 to 120n is switched to being connected with the metrology unit 130 to be measured, the circuit connection ports 1201 to 120n remain electrically connected to one of the ground wires 161 and 162 to ensure that the current loops 1001 to 100n can be grounded through one of the ground wires 161 and 162 to get rid of the static electricity in the current loops 1001 to 100n no matter if the circuit is being measured or not being measured.

Furthermore, the automatic ESD detection system 100 of the present invention further includes a communication unit 170 connected to the micro-controller 110. The communication unit 170 is controlled by the micro-controller 110 for transmitting the detection result to the remote monitor program 190 via the network 180. The remote monitor program 190 can be used to show the current loop with abnormal ESD based on the detection result.

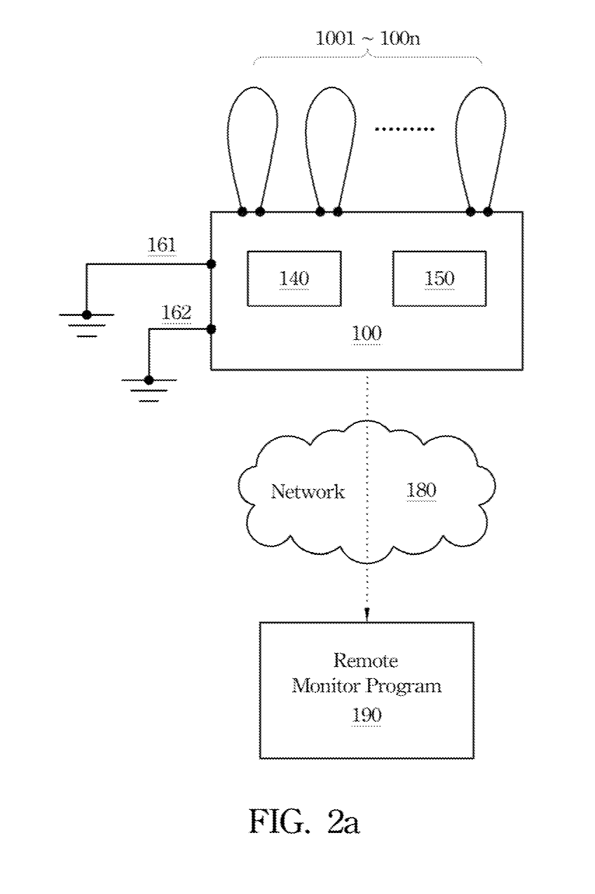

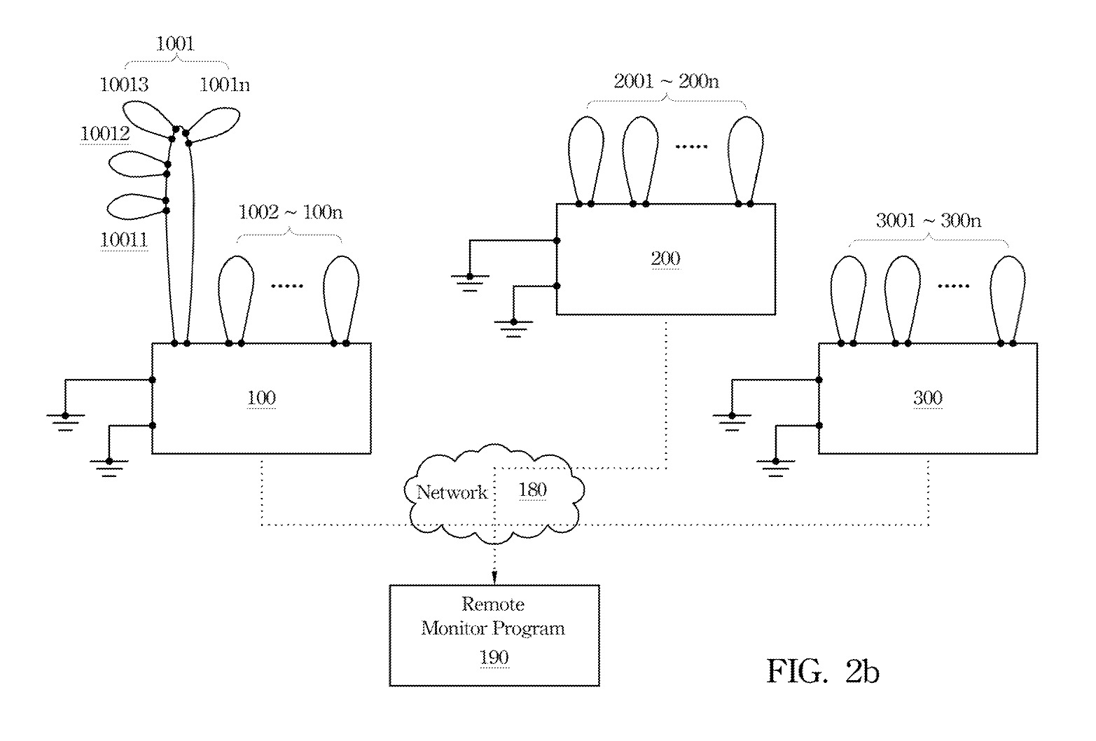

Refer to FIG. 2a and to FIG. 2b. FIG. 2a and FIG. 2b are schematic diagrams of an ESD detection system of the present invention applied on current loops. As shown in FIG. 2a, the automatic ESD detection system 100 of the present invention can connect the whole group of current loops 1001 to 100n, and respectively measure a resistance value of one of the current loops 1001 to 100n by periodically switching one of relay circuits of the circuit switching unit 140 to check if one of the current loops 1001 to 100n has abnormal ESD. At the same time, via the prompt unit 150 of the automatic ESD detection system 100, warning lights or warning sounds can be sent out based on the detection result to inform which current loop of the group of current loops 1001 to 100n has abnormal ESD.

In another embodiment shown in FIG. 2b, three automatic ESD detection systems 100, 200, and 300 are shown here simply as examples for explanation, but this embodiment of the present invention is not limited thereto. That implementing a plurality of the automatic ESD detection systems of the present invention not only can periodically detect the current loops 1001 to 100n but also can expand to connect a plurality of groups of current loops 2001 to 200n, current loops 3001 to 300n, and so on. A resistance value of one of the current loops 2001 to 200n is measured respectively via the automatic ESD detection system 200 to check if all the current loops 2001 to 200n have abnormal ESD. A resistance value of one of the current loops 3001 to 300n is measured respectively via the automatic ESD detection system 300 to check ifall the current loops 3001 to 300n has abnormal ESD.

Furthermore, as shown in FIG. 2b, the automatic ESD detection system of the present invention can further expand and then extend current loop 1001 in a tree-like branch structure. The automatic ESD detection systems of the present invention are installed in sub current loops 10011 to 1001n of the current loop 1001 to periodically measure the resistance values of the sub current loops 1001 to 1001n of the current loop 1001 to check if the sub current loops 1001 to 1001n have abnormal ESD. By using the automatic ESD detection system of the present invention, ESD of a plurality of current loops can be automatically detected when being measured, and then the conventional method which conducts measurements with respect to the plurality of current loops one by one in an artificial manner can be improved.

Although the present invention is disclosed with embodiments as above, it is not used to limit the present invention, and any one skilled in the art can make various changes and modifications without departing from the spirit and range of the present invention. Therefore, the contents of the present invention under protection depend on the following claims.

What is claimed is:

1. An automatic electrostatic discharge (ESD) detection system connected to a plurality of current loops for respectively detecting a plurality of electrical devices connected in sequence in each of the current loops and checking if the electrical devices have abnormal ESD, the automatic ESD detection system comprising:
a micro-controller used to obtain measurement data and process the measurement data, thereby generating a detection result and sending out the detection result externally;
a plurality of circuit connection ports respectively connected to the current loops;
a metrology unit used to'measure a resistance value of one of the current loops and transmit the resistance value back to the micro-controller;
a circuit switching unit controlled by the micro-controller to periodically switch one of the circuit connection ports to being connected with the metrology unit; and
a prompt unit controlled by the micro-controller for sending a prompt signal based on the detection result.

2. The automatic ESD detection system of claim 1, comprising two ground wires respectively and simultaneously connected to the circuit connection ports, wherein when one of the circuit connection ports is switched to being connected to the metrology unit, the one of the circuit connection ports remains electrically connected to one of the ground wires.

3. The automatic ESD detection system of claim 1, wherein the micro-controller compares the resistance value measured by the metrology unit with a predetermined value, and if the resistance value is greater than the predetermined value, it is determined that the current loop with the resistance value has abnormal ESD.

4. The automatic ESD detection system of claim 3, wherein the predetermined value is 2 ohm.

5. The automatic ESD detection system of claim 1, further comprising:
a communication unit connected to the micro-controller, wherein the communication unit is controlled by the micro-controller for transmitting the detection result to a remote monitor program.

6. The automatic ESD detection system of claim 5, wherein the remote monitor program is used to show the current loop with abnormal ESD based on the detection result.

7. An automatic ESD detection system connected to a plurality of current loops for respectively detecting a plurality of electrical devices connected in sequence in each of the current loops and checking if the electrical devices have abnormal ESD, the automatic ESD detection system at least comprising:
a micro-controller used to obtain measurement data and process the measurement data, thereby generating a detection result and sending out the detection result externally;
a plurality of circuit connection ports respectively connected to the current loops;
a metrology unit used to measure a resistance value of one of the current loops and transmit the resistance value back to the micro-controller;
a circuit switching unit controlled by the micro-controller to periodically switch one of the circuit connection ports to being connected with the metrology unit;
a prompt unit controlled by the micro-controller for sending a prompt signal based on the detection result; and
two ground wires respectively and simultaneously connected to the circuit connection ports;
wherein when one of the circuit connection ports is switched to be connected to the metrology unit, the one of the circuit connection ports remains electrically connected to one of the ground wires.

8. The automatic ESD detection system of claim 7, wherein the micro-controller checks if the resistance value measured by the metrology unit is greater than 2 ohm, and if the resistance value is greater than 2 ohm, it is determined that the current loop with the resistance has abnormal ESD.

9. The automatic ESD detection system of claim 7, further comprising a communication unit connected to the micro-controller, wherein the communication unit is controlled by the micro-controller for transmitting the detection result to a remote monitor program via a network.

10. The automatic ESD detection system of claim 9, wherein the remote monitor program is used to show the current loop with abnormal ESD based on the detection result.

11. An automatic electrostatic discharge (ESD) detection system connected to a plurality of current loops for respectively detecting a plurality of electrical devices connected in sequence in each of the current loops and checking if the electrical devices have abnormal ESD, the automatic ESD detection system comprising:
a micro-controller used to obtain measurement data and process the measurement data, thereby generating a detection result;
a plurality of circuit connection ports respectively connected to the current loops;
a metrology unit used to measure a resistance value of one of the current loops and transmit the resistance value back to the micro-controller;
a circuit switching unit controlled by the micro-controller to periodically switch one of the circuit connection ports to being connected with the metrology unit;
a prompt unit controlled by the micro-controller for sending a prompt signal based on the detection result;
two ground wires respectively and simultaneously connected to the circuit connection ports, wherein when one of the circuit connection ports is switched to being connected to the metrology unit, the one of the circuit connection ports remains electrically connected to one of the ground wires; and
a communication unit connected to the micro-controller, wherein the communication unit is controlled by the micro-controller for transmitting the detection result to a remote monitor program via a network, and the remote monitor program is used to show the current loop with abnormal ESD based on the detection result.
